(19) United States
(12) Patent Application Publication
(10) Pub. No.: US 2009/0267806 A1
(43) Pub. Date: Oct. 29, 2009

(54) Electrical Circuit

(76) Inventors: Juergen Blank, Gernrode (DE); K.-Ulrich Hildebrandt, Gernrode (DE); Lothar Goede, Gernrode (DE); Helmut Plaettner, Gernrode (DE)

Correspondence Address: LAW OFFICES OF KARL HORMANN, 86 SPARKS STREET, CAMBRIDGE, MA, 02138, US

(21) Appl. No.: 12/087,257

(22) PCT Filed: Sep. 20, 2007
(86) PCT No.: PCT/DE2007/001694

§ 371 Date: Jun. 29, 2008

(30) Foreign Application Priority Data
Sep. 19, 2006 (DE) 10 2006 043 891.4

(51) Int. Cl. H03M 11/00

(52) U.S. Cl. 341/22

(57) ABSTRACT

An electrical circuit for controlling at least one electrical load and at least one function thereof by providing, in the active line of an AC circuit, a modulation switching circuit and a plurality of function keys series-connected with at least with the at least one electrical load and a demodulation unit upstream thereof.

### BACKGROUND OF THE INVENTION

1. Field of the Invention

The invention relates to an electrical circuit for the control of a plurality of electrical loads and of the functions thereof.

It is particularly suitable for upgrading existing electrical circuits in buildings such as, for instance, of ventilation fans and lighting systems which cannot easily be supplemented without extensive measures in terms of the structure and electrical installations.

2. The Prior Art

A circuit for controlling an electrical load (for instance, the circuit of a chandelier with a plurality of electric current circuits) is known which by repeatedly actuating one switch allows a few functions to be performed, as by repeated on and off switching and evaluation of the number switching intervals or switching pulses by electronic circuitry.

Its disadvantage is that the electric load must be provided with such electronic circuitry and that switching five times or more for attaining one state or another is unacceptable.

Also known is a circuit in which different frequencies or pulse length modulations can be realized by modulating the mains voltage between active line and neutral line or by additional modulation when the phase is at zero. The drawback of such an arrangement is that active and neutral lines must always be present at the switch, which is not the case in simple existing on/off switches in alternating current circuits.

Furthermore, infrared remote switching circuits are known for the remote control of electrical loads.

Their disadvantage resides on the one hand in a relatively complex internal or external receiver installed at the apparatus or load and, on the other hand, in the need for a transmitter with a battery as a separate current supply.

Also, a cable-connected electrical circuit is known for the control of several functions of an electrical load and its functions within a low current net circuit with an active and a neutral line, having, for the control of an electrical load in the active line, a switching unit with several function keys series-connected with one or more electrical loads, with a further switching unit being present ahead of each electrical load.

Its disadvantage is that in order to energize the diodes for a modulation, active and neutral lines must either be present or they must be installed. This, in turn, requires, for instance during installation of such circuits and, more so, during upgrading existing mains circuits in living, business and function rooms significant time and effort for installing the neutral line. Moreover, such a circuit suffers from a relatively long reaction time. At a minimum signal-to-noise ratio this may result in safety problems and may lead to transmission failure from general net failures. In illumination equipment connected in this manner, for instance, large signal-to-noise ratios may result in flickering (EP 1 066 690 B1).

Moreover, a system for the zero point data transmission is known for power lines.

The disadvantage of such circuits is that they require uninterrupted active and neutral lines which cannot be provided in a number of special applications, as, for instance, where simple on/off circuits are present which depend on phase interruptions and which have no neutral line (EP 1,134,910 A2).

Also, a burst signal transmission system is known for providing electrical circuits.

Its disadvantage is that for rendering the circuit functional, the transmitters integrated in the circuit always require an EMK by way of an active and a neutral line or battery (EP 0 370 943 A2).

Furthermore, a cable-connected lamp control system is known in which signals are transmitted by changing the supply voltage.

Here, too, it is disadvantageous that the signal-modulating current circuit is connected to the active and neutral lines and that for this reason the system is unsuitable for circuits lacking a neutral line (WO 91/030093 A1).

Finally, a load control system with cable-connected signaling is known.

Its drawback is that to modulate signals in these systems, there must always be present an active and a neutral line which makes this system unsuitable for circuits without neutral line (GB 2 050 662 A).

### OBJECT OF THE INVENTION

It is an object of the invention to provide a cable-connected circuit for the control of a plurality of different electrical loads and/or for the control of several different functions thereof in a single alternating current circuit.

In this connection, the operating unit for controlling the functions is to be integrated solely in the voltage-carrying line, with neither additional EMK by battery or transformer being required for the function of the operating unit nor the need for connecting a neutral line.

### SUMMARY OF THE INVENTION

In the accomplishment of these and other objects the invention provides for an electrical circuit in which, for the control of at least one electrical load 28, at least one modulation switching unit 21 with a plurality of function keys 12, 13, 14, 15, 16, 17 is series-connected, by means of terminals A and B to one or more electrical loads 28, 28a, in an alternating current circuit having an active line 26b and a neutral line 26a, and a demodulation switching unit 22 is provided ahead of the electrical loads.

The modulating switching unit 21 with terminals A and B and at least two function keys 12, 13, 14, 15, 16, 17 is structured such that

a) within it, between active line 26b connected to terminal A and line 26c connected to terminal B, there is provided a diode 3 the cathode of which is connected to line 26b and the anode of which is connected to a modulating line 26c, and

b) in parallel therewith, between line 26b and modulating line 26c there are provided a plurality of series-connected homo-poled fast diodes constituting diode group 1 and diode group 2 poled opposite to diode 3, and

c) parallel therewith, between diode group 1 and the other diode group 2 as well as the modulating line 26c, there is provided a field effect transistor 4 which is by a line 29 is connected to terminals C of double diodes of function keys 12, 13, 14, 15, 16, 17 as well as to a code generator 8 at one of the contacts PIN 014 thereof such that the field effect transistor 4 is connected in parallel to diode group 2, with the source being connected to the last cathode of diode group 2, the drain being connected to the anode thereof and the gate being connected to the function keys 12-17 via the double diodes C, D thereof for decoupling, and

d) a modulation field effect transistor 5 is present between line 26b and line 26c and also connected, by a line 11, to the code generator 8 at one of its code output contact PIN 011 such that the modulation field effect transistor 5 is connected parallel to the diode groups 1 and 2 with its source connected to the last cathode of diode group 2, its gate connected to the data output of the code generator 8 at one of the code output terminals PIN 011 thereof, and

e) a rectifier diode being provided in line 26b, its cathode being connected to a feed line 32 of the code generator 8, and

f) a capacitor 7 is present between voltage feed line 32 of the code generator 8 and line 26c, and

g) the voltage feed line 32 is connected to the code generator 8 at one of the positive supply voltage terminals PIN 010 thereof, and

h) line 26c is connected to the function keys 12, 13, 14, 15, 16, 17 and, by a line 31, to the code generator 8 at the negative supply voltage contact PIN 09 thereof, and

i) that, for decoupling, the double diodes of the function keys 12, 13, 14, 15, 16, 17 are connected, by their contacts D, via lines to the code generator 8 at at least two or more of the control input terminals PIN 06, 07, 08, 09, 016, 017, 018 thereof, and

j) that the voltage feed line 32 is connected to one of the terminals PIN 010 and another one of the code generator terminals PIN 014 of the code generator 8 by way of a pull up resistor 9 and line 29, and

k) external oscillator connection terminals PIN 012 and PIN 013 of the code generator 8 are connected to each other by an external oscillator resistor 10.

The demodulation switching unit 22 ahead of the electrical loads 28, 28a and provided with a power supply unit 23 for maintaining a minimum current for a stand-by function is connected to the neutral line 26a and to the modulation line 26c from terminal B of the modulation switching unit 21.

Within the demodulation switching unit 22 an electronic decoder 24 functioning as a micro processor is connected downstream from the power supply unit 23. The micro processor is also directly connected to the neutral line 26a and, by way of a high-pass filter 25 and/or by a zero point recognition 30 to line 26c from terminal B of modulation switching unit 21.

At least one electronic or electromechanical power switch 27, 27a is arranged downstream from the decoder 24, the power switch 27, 27a being directly connected in parallel to the neutral line 26a and the modulation line 26c.

The power switch or switches 27, 27a are connected to the electrical load or loads 28, 28a by means of terminals E, F and/or G, H.

Several modulation switching units 21 may also be interconnected in series.

The advantages of the invention are that, at relatively low complexity, various further loads and/or functions can be connected to a simple alternating current circuit provided with series-connected on/off switches or two-way switches to an electrical load. The technical complexity in terms of material and labor may thus be significantly minimized. The pole terminals A and B of the lines may be interchanged or exchanged without damaging the system of the electrical circuit. This facilitates installation. It is especially easy to install the circuit in accordance with the invention into existing electrical installations in buildings by leaving the entire simple net in a building unchanged and by only exchanging on/off switches or two-way switches for modulation switching units of the same size and to equip even ceiling vents and/or illumination systems with such a demodulation switching unit. This is of particular advantage, for instance, where a ceiling fan with integrated illumination is to replace an existing fixture since in this manner the illuminating means may be dimmed or switched at different levels of brightness and/or in different numbers and/or where ceiling fans may be simultaneously or separately switched on or off, or where they may be operated at different levels of power or rotational directions. It is also possible to integrate a plurality of switching units in accordance with the invention. To carry out a modulation of bursts on the half-waves of the amplitudes ensures significant immunity from general net malfunctions or other functional failures, such as, for instance, light flickering. The circuit in accordance with the invention is characterized by extremely short reaction times.

### DESCRIPTION OF THE SEVERAL DRAWINGS

The novel features which are considered to be characteristic of the invention are set forth with particularity in the appended claims. The invention itself, however, in respect of its structure, construction and lay-out, as well as manufacturing techniques, together with other objects and advantages thereof, will be best understood from the following description when read with reference to the drawings, in which:

FIG. 1 is a circuit diagram of the modulation switching unit 21 of the function key;

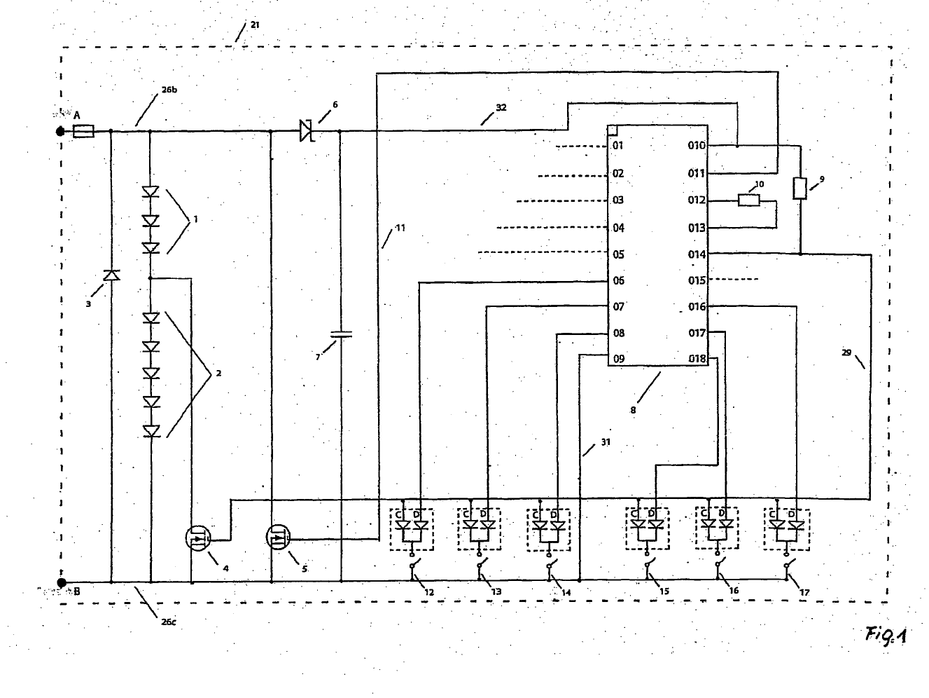

FIG. 2 is a circuit block diagram of the demodulation circuit unit integrated into the load; and

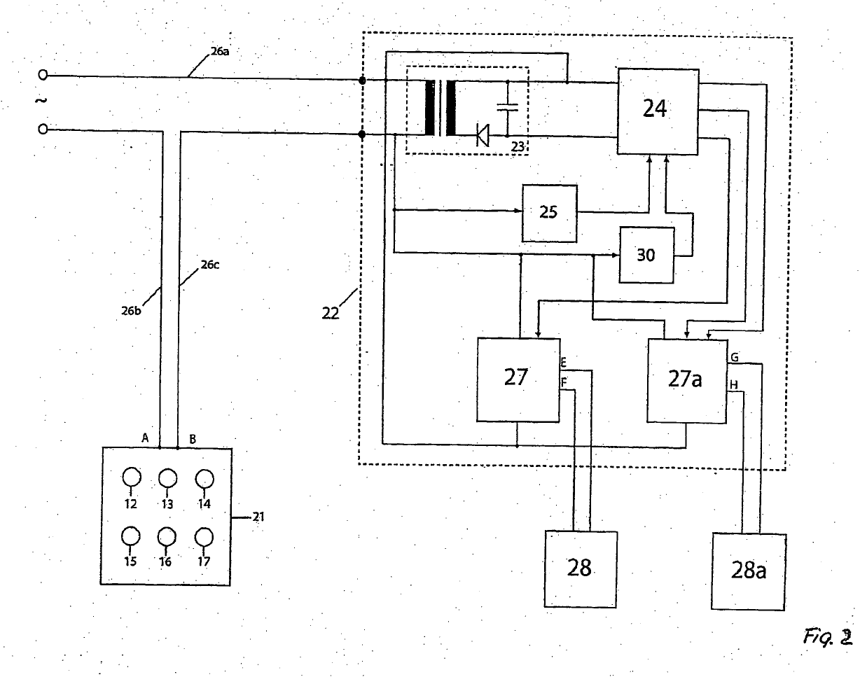

FIG. 3 is a schematically shown modulation curve with bursts for switching pulses.

### DETAILED DESCRIPTION OF THE PREFERRED EMBODIMENT

A ceiling-mounted air exhaust fan combined with lamps is to be connected with active and neutral line to the net by a simple electric system mounted under plaster. Initially, the inventive modulation switching unit 21 with function keys 12-17 is series-connected in the line between the ceiling fan as one electrical load 28 and the lamps 28a and the net to replace the switch originally provided as an on/off switch. Appropriately associated function keys may be actuated to control several different functions, such as on/of and different revolutions of the ceiling exhaust fan and/or different levels of illumination of the lamp and/or the switching of different numbers of lamps. For this purpose the combination ceiling-mounted air exhaust fan and lamp is provided with a demodulation switching unit 22 and is connected to the existing two-lead net.

During operation of the circuit electrical power may be switched from 1 W at stand-by operation to several hundred Watts. In a series circuit currents from about 1 mA to several A may result. During a half-wave a low voltage drop is affected across the diode group 1 which feeds the code generator 8 and renders the field effect transistor 4 conductive which shunts the diode group 2. The diode 6 and the capacitor 7 serve to decouple and buffering of energy. The diode 3 serves to let the opposite half-wave pass.

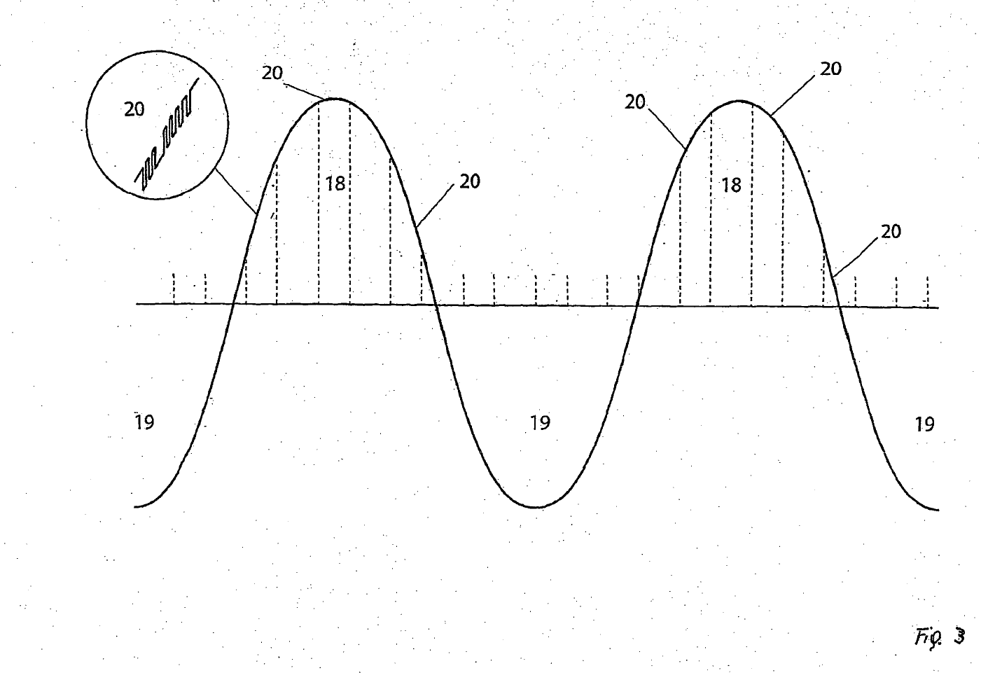

FIG. 3 graphically depicts the modulation of the alternating current during signal transmission.

One or more function keys 12 to 17 are actuated for transmitting a function control signal from the function key switch i.e. the modulation switch unit 21 to the loads 28 and 28a. The associated double diode C thus lowers the gate voltage of the field effect transistor 4 by way of the resistor 9 which causes the field effect transistor 4 to open. At the same time the clock system of the code generator 8 (pin 014) begins to resonate, with the frequency of the base pulse being determined by the size of the external oscillator resistor 10. The code generator 8 receives the information about which key or keys have been actuated from contact D of the double diode associated with the respective actuated function key or keys 12 to 17. The generated code diagrams emitted from the output terminal 011 of the code generator 8 thus control the gate of the field effect transistor 5 which in synchronism with the code signal electrically shunts the diodes of diode group 1 and of diode group 2. Following the control operation, the diodes of diode group 2 will be shunted by the field effect transistor 4 in order to keep the loss of power as small as possible. On the other hand, the diodes of diode group 2 are required if necessary to increase the degree of modulation or signal-to-noise ratio. Code diagrams appear at pin 011 of the code generator 8 which correspond to a given actuated function key 12 to 17. The optimum chronological interaction between frequency of the main current circuit, the length of the code and the synchronous gap between the modulation bursts 20 is depicted in the upper half-wave in FIG. 3. As a rule, the lower half-wave is not modulated and passes unaltered through the diode 3.

To demodulate the modulated half-wave in the demodulation switching unit 22, the code signal is split by the high pass filter 25 from the low-frequency alternating current and is fed to the decoder 24 which ignores incomplete and faulty modulation bursts 20. To increase the functionality there will be a succession of several modulation bursts 20. The decoder 24 will then evaluate several complete transmitted modulation bursts 20 and examine them for uniformity. The electrical power switches 27, 27a will switch and/or dim individual loads 28, 28a with dimming resulting from the zero-crossing recognition 30.

1. (canceled)

2. (canceled)

3. An electrical circuit for controlling one of at least one electrical load and at least one function thereof in a low voltage mains circuit having an active line having first and second sections and a neutral line, comprising:
a modulation switching unit comprising a plurality of function keys series-connected with the at least one electrical load and a first diode having a cathode connected to the first section and an anode connected to the second section of the active line and, in parallel to the diode between the first and second sections of the active line, first and second groups of a plurality of equally poled fast diodes poled opposite the first diode;
a double diode comprising first and second contacts and connected to each function key;
a code generator comprising a plurality of contacts;
a field effect transistor connected between the first and second groups of the fast diodes and the second section of the active line and having a source connected to the last cathode of the second group of fast diodes, a drain connected to the first anode thereof and a gate connected for decoupling to the function keys by way of the first contact of every double diode and to a first contact of the code generator;
a modulating field effect transistor having a source connected to the last cathode of the second group of fast diodes, a drain connected to the anode of the first diode of the first group of fast diodes and a gate connected to a second contact of the code generator;
a rectifier diode connected between the first section of the active line and, by its cathode, to a third contact of the code generator;
a capacitor connected between the third contact of the code generator and the second section of the active line;
the second section of the active line being connected to the function keys and to a fourth contact of the code generator;
the double diodes being by their second contacts connected to at least two contacts of the code generator;
the first and third contacts of the code generator being connected to each other by a pull-up resistor;
fourth and fifth contacts of the code generator being connected to each other by an oscillator;
a demodulation switching unit ahead of the electrical loads connected to the neutral and active lines and provided with a power supply for the supply of a minimum current for stand-by operation;
an electronic decoder being connected as a micro processor downstream of the power supply and to the modulation switch unit by at least one of a high-pass filter and zero-point recognition;
a power switch being connected downstream of the decoder parallel to the neutral line and active line and to the electric loads.

4. The electrical circuit of claim 3, wherein a plurality of modulation switch units are connected in series.
